(19) United States
(12) Patent Application Publication
(10) Pub. No.: US 2024/0303386 A1
(43) Pub. Date: Sep. 12, 2024

(54) COMPUTER-IMPLEMENTED METHOD AND SYSTEM FOR CREATING A SCENARIOS LIBRARY

(71) Applicant: dSPACE GmbH, Paderborn (DE)

(72) Inventors: Hagen HAUPT, Paderborn (DE); Thorsten PUESCHL, Paderborn (DE); Jann-Eve STAVESAND, Paderborn (DE)

(73) Assignee: dSPACE GmbH, Paderborn (DE)

(21) Appl. No.: 18/597,495

(22) Filed: Mar. 6, 2024

(30) Foreign Application Priority Data
Mar. 6, 2023 (DE) 10 2023 105 379.5

(51) Int. Cl. G06F 30/15

(52) U.S. Cl. CPC G06F 30/15

(57) ABSTRACT

A computer-implemented method and system for the criteria-based creation of a scenarios library having virtual vehicle environments, for testing highly automated driving functions of a motor vehicle. Using predetermined criteria, a first scenario data set is determined representing a driving situation of interest and comprised by the sensor data. The first scenario data set, representing the driving situation of interest, is compared with second scenario data sets included in the scenarios library. A computer-implemented method for validating a model quality of a simulation model for performing a highly automated driving function of a motor vehicle is also provided.

This nonprovisional application claims priority under 35 U.S.C. § 119(a) to German Patent Application No. 10 2023 105 379.5, which was filed in Germany on Mar. 6, 2023, and which is herein incorporated by reference.

### BACKGROUND OF THE INVENTION

### Field of the Invention

The present invention relates to a computer-implemented method for the criteria-based creation of a scenarios library, having virtual vehicle environments, for testing highly automated driving functions of a motor vehicle.

The present invention furthermore relates to a computer-implemented method for validating a model quality of a simulation model for performing a virtual test of a highly automated driving function of a motor vehicle.

The invention further relates to a system for the criteria-based creation of a scenarios library, having virtual vehicle environments, for testing highly automated driving functions of a motor vehicle.

### Description of the Background Art

The aim in the development and the virtual testing of highly automated driving functions of a motor vehicle is to achieve the most exact possible coverage of all driving situations occurring in real road traffic.

EP 3792768 A1, which corresponds to US 2021/0078590, discloses a method for constructing a test scenario library, comprising determining scenario categories of scenario elements, wherein the scenario categories comprise a perceptual type or a policy type; selecting policy-type elements from the scenario elements each with the determined scenario category; constructing a test scenario library according to the policy-type elements; and verifying the test scenario library and updating the test scenario library according to a verification result.

In order to be able to make a homologation statement regarding sufficient test coverage of the highly automated driving functions of a motor vehicle, it is necessary, however, to detect all driving situations possible that occur in real road traffic, to include them in a scenarios library, and to test them virtually.

Such virtual test scenarios, which are used for the evaluation of the highly automated driving function or a highly automated driving system as part of a safety verification, can therefore be derived from the driving situations detected in real road traffic.

In order to achieve the highest possible coverage of driving situations occurring in real road traffic by the scenarios library, it is therefore necessary for the scenarios library to comprise a sufficient number of data sets of virtual test scenarios.

As a result, there is a need to improve existing methods and systems for creating a scenarios library, having virtual vehicle environments, for testing highly automated driving functions of a motor vehicle so that the scenarios library enables optimum test coverage of the driving situations occurring in real road traffic.

### SUMMARY OF THE INVENTION

It is therefore an object of the invention to provide a computer-implemented method and system for the criteria-based creation of a scenarios library, having virtual vehicle environments, for testing highly automated driving functions of a motor vehicle, which enables the creation of a scenarios library having an optimal test coverage of driving situations occurring in real road traffic.

Further, it is an object of the invention to validate, on the basis of the created scenarios library, a model quality of a simulation model, executing the automated driving function.

The object is achieved according to an example of the invention by a computer-implemented method for the criteria-based creation of a scenarios library, having virtual vehicle environments, for testing highly automated driving functions of a motor vehicle.

Furthermore, the object is achieved according to an example of the invention by a computer-implemented method for validating a model quality of a simulation model for performing a virtual test of a highly automated driving function of a motor vehicle.

Also, the object is achieved according to an example of the invention by a system for the criteria-based creation of a scenarios library, having virtual vehicle environments, for testing highly automated driving functions of a motor vehicle.

Moreover, the object is achieved according to an example of the invention by a computer program product.

The invention relates to, in an example, a computer-implemented method for the criteria-based creation of a scenarios library, having virtual vehicle environments, for testing highly automated driving functions of a motor vehicle.

The method comprises providing, in particular pre-captured, sensor data of a motor vehicle journey detected by at least one environment sensing sensor.

Furthermore, the method comprises determining, using predefined criteria, a first scenario data set, representing a driving situation of interest and comprised by the sensor data.

The driving situation of interest can be given by a time segment of a data stream of the sensor data, which are extracted from the data stream and stored or temporarily stored as, in particular, an abstract first scenario data set.

Moreover, the method can comprise comparing the first scenario data set, representing the driving situation of interest, with, in particular abstract, second scenario data sets, included in the scenarios library.

The method further can comprise creating a third scenario data set, representing a logical test scenario in the scenarios library or generating a request to create the third scenario data set representing the logical test scenario, in the scenarios library, if the driving situation of interest, determined by the first scenario data set, is not covered by any of the second scenario data sets comprised by the scenarios library.

The invention relates further to a computer-implemented method for validating a model quality of a simulation model for performing a virtual test of a highly automated driving function of a motor vehicle.

The method can comprise providing a first scenario data set, extracted from the sensor data of a motor vehicle journey detected by at least one environment sensing sensor.

Furthermore, the method can comprise providing a third scenario data set, comprised by a scenarios library, for testing highly automated driving functions of a motor vehicle.

The method additionally can comprise performing a virtual test of the test scenario, comprised by the third scenario data set, using the simulation model.

Moreover, the method can comprise comparing the first scenario data set, extracted from the sensor data of the motor vehicle journey detected by the at least one environment sensing sensor, with an output of the simulation model.

The invention further relates to a system for the criteria-based creation of a scenarios library, having virtual vehicle environments, for testing highly automated driving functions of a motor vehicle. The system can comprise at least one environment sensing sensor which is designed to provide, for example pre-captured, sensor data of a motor vehicle journey.

Furthermore, the system can comprise a determination unit which is designed, using predefined criteria, to determine an, in particular abstract, first scenario data set, representing a driving situation of interest and comprised by the sensor data.

The system moreover can comprise a comparison unit which is designed to compare the first scenario data set, representing the driving situation of interest, with, for example, abstract, second scenario data sets, included in the scenarios library.

Further, the system can comprise a generation unit which is designed to create a third scenario data set, representing a logical test scenario in the scenarios library or to generate a request to create the third scenario data set representing the logical test scenario in the scenarios library if the driving situation of interest, determined by the first scenario data set, is not covered by any of the second scenario data sets comprised by the scenarios library.

The invention additionally relates to a computer program product with a computer program comprising software for carrying out the method according to the invention, wherein the computer program is executed on a computer.

A scenario can be defined as the temporal development of a series of scenes. A scene can be interpreted as a snapshot of the surroundings, including dynamic and static objects. Each scenario starts with an initial scene and is developed over time by the actions and events of these objects.

Abstract scenarios are derived from functional scenarios. For this purpose, the informal scenario can be recorded in machine-readable form. This is possible by identifying the occurring relations and restrictions of the scenario and binding them to an ontology. An ontology may be essentially a digital tool for storing knowledge about properties and relations between entities.

Entities are the actors occurring in traffic. A logical scenario can be obtained when the relations and constraints defined in the abstract scenario are parameterized and restricted to value ranges with corresponding distributions of the parameters.

If a valid value is selected from each of these value ranges of the logical scenario and these relations and constraints are instantiated in concrete terms, a concrete scenario is obtained.

Therefore, an infinite number of different logical scenarios can be derived from an abstract scenario, and correspondingly an infinite number of concrete scenarios.

An idea of the present invention is to create a scenarios library using scenario data sets, which enables an optimal test coverage of driving situations occurring in real road traffic.

To achieve this, it is of critical importance to determine according to predefined criteria which scenario data sets are to be included in the scenarios library and which are not.

In this way, coverage of a test scenario taxonomy can be completed with the inclusion of each additional scenario data set representing a logical test scenario.

The logical test scenario can then be simulated by a simulator, e.g., as part of a scenario-based test.

It can therefore be safely and comprehensibly argued that the automated driving function is sufficiently safe. The method of the invention enables the determination of the residual risk and the verification and quantification of the test coverage in a methodically comprehensible manner. This represents a core problem in the approval of automated driving functions.

The method can comprise that the first scenario data set may be formed by a time segment of a data stream comprised by the sensor data, and wherein the second scenario data sets, comprised by the scenarios library, may be formed by a machine-readable, abstract description of a traffic situation of interest, in particular a test scenario.

The abstract description of the traffic situation of interest can also be referred to as an abstract scenario or abstract test scenario. The time interval of the data stream comprised by the sensor data can therefore be compared with the machine-readable, abstract description of the traffic situation of interest.

The method can also comprise that if, after evaluation of a predetermined amount of sensor data corresponding to a specific mileage of the motor vehicle, each determined first scenario data set is covered by the second scenario data sets included in the scenarios library, a message confirming a completeness of the scenarios library is generated.

As a result, a sufficient testing of the automated driving function can be demonstrated in this way, because a residual probability of new test scenarios occurring that are not comprised by the scenarios library becomes increasingly lower as the amount of evaluated sensor data increases.

Further, the method can comprise that if the determined first scenario data set, comprised by the sensor data and representing the driving situation of interest, is not covered by one of the second scenario data sets, comprised by the scenarios library, a second scenario data set representing an abstract scenario can be generated from the first scenario data set.

Coverage of abstract scenarios in the scenarios library can thus be completed.

The method can comprise storing the third scenario data set, representing the logical test scenario, in the scenarios library. A concrete test scenario can then be created on the basis of the stored data set representing the logical test scenario.

The scenario database therefore can comprise abstract scenarios and logical test scenarios, which may be linked but are different data sets.

The method can comprise that metadata are stored in the scenarios library for the second scenario data sets and/or the third scenario data sets. Further, the metadata can include, for example, information on a file of the sensor data, boundary conditions of the traffic situations, which second scenario data set is included in the scenarios library determined as belonging to the first scenario data set representing the driving situation of interest and comprised by the sensor data, scenario parameters, speed of at least one motor vehicle, and/or a distance between motor vehicles, which can all be stored in the scenarios library for the second scenario data sets and/or the third scenario data sets. The above-mentioned scenario parameters are listed merely as examples. The use of a large number of other known scenario parameters is conceivable. A relationship can be established between the first and second scenario data sets with the use of metadata.

The method can also comprise that the third scenario data set, representing the logical test scenario, can be generated using an algorithm which receives sensor data and an abstract test scenario, comprised by the sensor data, as input data.

The algorithm can be a machine learning algorithm such as, for example, a neural network. The sensor data can be, e.g., camera image data, radar image data, or LiDAR data.

The method can comprise that the determination of the first scenario data set, representing the driving situation of interest and comprised by the sensor data, is performed by classifying a driving situation of interest into classes representing abstract scenarios. An automated extraction or determination of abstract scenarios based on the underlying sensor data can thus take place in an advantageous way.

The method can comprise that the determination, using predetermined criteria, of the first scenario data set, representing the driving situation of interest and comprised by the sensor data, and the comparison of the first scenario data set, representing the driving situation of interest, with second scenario data sets, comprised by the scenarios library, can be combined such that, in the comparison step, filtering of the sensor data is carried out using the predetermined criteria.

Filtering the sensor data stream according to the predefined criteria therefore makes it possible to identify relevant driving situations of interest in an advantageous way.

The method can comprise that a determination of the predetermined criteria for determining the first scenario data set, representing the driving situation of interest and comprised by the sensor data, is performed using a system weakness analysis.

System weakness analysis can be used to deductively identify weaknesses in the system and to identify so-called triggering conditions, i.e., situations, combinations of parameters or scenes that could potentially lead to dangerous situations or system degradations, which form the basis for defining key performance indicators (KPIs).

Because relevant situations only occur at certain times during the test drives, the measurement data can be filtered in a first step, i.e., the step of determining the first scenario data set, representing the driving situation of interest and comprised by the sensor data, using predefined criteria and based on defined KPIs. These KPIs result from the upstream system weakness analysis. Alternatively, other risk analysis methods such as, for example, FTA or FTMA can be used for this purpose.

The method can also comprise that the scenarios library comprises data of a test scenario taxonomy, in particular a test scenario ODD (Operational Design Domain) taxonomy, and wherein the test scenario taxonomy can be directed to a specific system to be tested.

The test scenario taxonomy thus defines the test coverage to be achieved, which, when achieved, enables a homologation statement to be made with regard to sufficient test coverage of the vehicle's highly automated driving functions.

The method can comprise that if the first scenario data set, extracted from the sensor data of the motor vehicle journey detected by the at least one environment sensing sensor, and the output of the simulation model have a similarity exceeding a predetermined level, a validity of the algorithm for executing the highly automated driving functions of the motor vehicle is confirmed.

It can thus be compared how the model, trained using the second scenario data sets and executing the highly automated driving function of the motor vehicle, behaves in a virtual test compared to the traffic situations obtained from real test drives.

The features of the computer-implemented method described herein for the criteria-based creation of a scenarios library, having virtual vehicle environments, for testing highly automated driving functions of a motor vehicle are also disclosed for the system for the criteria-based creation of a scenarios library, having virtual vehicle environments, for testing highly automated driving functions of a motor vehicle and vice versa.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a flowchart of a computer-implemented method for the criteria-based creation of a scenarios library, having virtual vehicle environments, for testing highly automated driving functions of a motor vehicle according to a preferred embodiment of the invention;

FIG. 2 shows a flowchart of a computer-implemented method for validating a model quality of a simulation model for performing a virtual test of a highly automated driving function of a motor vehicle according to the preferred embodiment of the invention; and

FIG. 3 shows a diagram of a system for the criteria-based creation of a scenarios library, having virtual vehicle environments, for testing highly automated driving functions of a motor vehicle according to the preferred embodiment of the invention.

### DETAILED DESCRIPTION

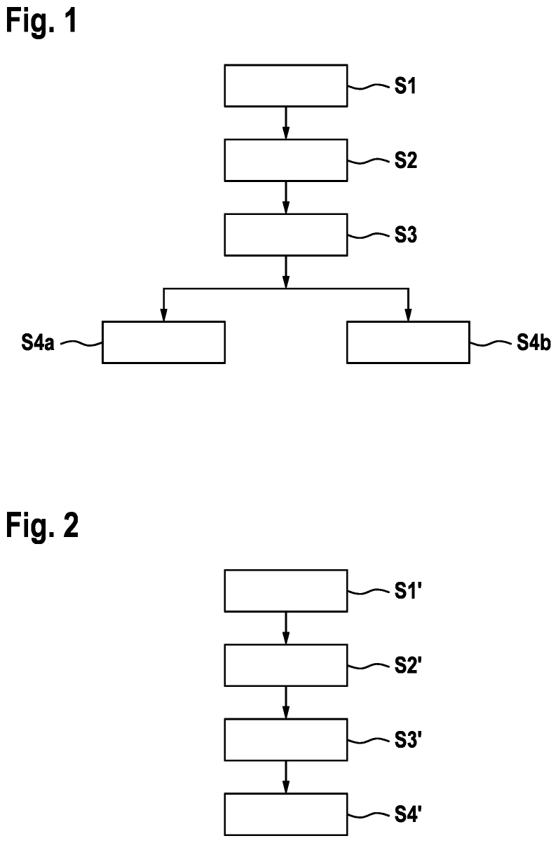

FIG. 1 shows a flowchart of a method for the criteria-based creation of a scenarios library 10, having virtual vehicle environments, for testing highly automated driving functions of a motor vehicle.

The method comprises providing S1, in particular pre-captured, sensor data 12 of a motor vehicle journey detected by at least one environment sensing sensor 26.

Environment sensing sensor 26 can be formed, for example, by a vehicle-side environment sensing sensor. Alternatively, environment sensing sensor 26 can be formed by an environment sensing sensor positioned in an environment of the motor vehicle. Such an environment sensing sensor can be attached, e.g., to a building, a traffic sign, a traffic light, and/or a drone.

Furthermore, the method comprises determining S2, using predetermined criteria, an, in particular abstract, first scenario data set 16, representing a driving situation of interest 14 and comprised by sensor data 12, and comparing S3 the first scenario data set 16, representing the driving situation of interest 14, with, in particular abstract, second scenario data sets 18 included in scenarios library 10.

Moreover, the method comprises creating S4a a third scenario data set (22), representing a logical test scenario, in scenarios library 10 or generating S4b a request to create the third scenario data set (22), representing the logical test scenario, in scenarios library 10 if the driving situation of interest 14, determined by first scenario data set 16, is not covered by any of the second scenario data sets 18, comprised by scenarios library 10.

The first scenario data set 16 is formed by a time segment of a data stream comprised by sensor data 12. Second scenario data sets 18, comprised by scenarios library 10, are further formed by a machine-readable, abstract description of a traffic situation of interest, in particular a test scenario.

If, after evaluation of a predetermined amount of sensor data 12, corresponding to a certain mileage of the motor vehicle, each determined first scenario data set 16 is covered by second scenario data sets 18 included in scenarios library 10, a message 20 confirming a completeness of scenarios library 10 is generated.

Further, if the determined first scenario data set 16, representing the driving situation of interest 14 and comprised by sensor data 12, is not covered by one of the second scenario data sets 18 comprised by scenarios library 10, a third scenario data set 22 representing an abstract scenario is generated from first scenario data set 16. Third scenario data set 22 representing the logical test scenario is then stored in scenarios library 10.

Metadata, in particular information on a file of sensor data 12, on boundary conditions of the traffic situations, and/or which second scenario data set 18, included in scenarios library 10, the determined first scenario data set 16, representing the driving situation of interest 14 and comprised by sensor data 12, is associated with, and scenario parameters, in particular a speed of at least one motor vehicle and/or a distance between motor vehicles, are stored in scenarios library 10 for second scenario data sets 18 and/or third scenario data sets.

Third scenario data set 22 representing the logical test scenario is generated using an algorithm which receives sensor data 12 and an abstract test scenario, comprised by sensor data 12, as input data.

The determining S2 of first scenario data set 16, representing the driving situation of interest 14 and comprised by sensor data 12, is carried out by classifying a driving situation of interest 14 into classes representing abstract scenarios.

Furthermore, the determining S2, using predetermined criteria, of first scenario data set 16, representing the driving situation of interest 14 and comprised by sensor data 12, and the comparing S3 of first scenario data set 16, representing the driving situation of interest 14, with second scenario data sets 18, comprised by scenario library 10, can be combined such that in the comparison step S3, a filtering of sensor data 12 is performed using the predetermined criteria.

Further, a determination of the predetermined criteria for determining first scenario data set 16, representing the driving situation of interest 14 and comprised by sensor data 12, is performed using a system weakness analysis.

Scenarios library 10 comprises data from a test scenario taxonomy, in particular a test scenario ODD taxonomy. The test scenario taxonomy in this regard is directed to a specific system 24 to be tested, for example, to a specific automated driving function and/or system.

FIG. 2 shows a flowchart of a computer-implemented method for validating a model quality of a simulation model for performing a virtual test of a highly automated driving function of a motor vehicle according to the preferred embodiment of the invention.

The method comprises providing S1′ a first scenario data set 16, extracted from sensor data 12 of a motor vehicle journey detected by at least one environment sensing sensor 26.

Furthermore, the method comprises providing S2′ a third scenario data set 22, comprised by a scenarios library 10, for testing highly automated driving functions of a motor vehicle.

The method additionally comprises performing S3′ a virtual test of the test scenario, comprised by third scenario data set 22, using the simulation model.

Moreover, the method comprises comparing S4′ the first scenario data set 16, extracted from sensor data 12 of the motor vehicle journey detected by the at least one environment sensing sensor 26, with an output of the simulation model.

If the first scenario data set, extracted from sensor data 12 of the motor vehicle journey detected by the at least one environment sensing sensor 26, and the output of the simulation model have a similarity exceeding a predetermined level, a validity of the algorithm for executing the highly automated driving functions of the motor vehicle is confirmed.

The validation of the simulation model thus takes place using the third scenario data set or a plurality of third scenario data sets in a simulator.

According to a further preferred embodiment, it is provided that after each generation of a third scenario data set representing a logical test scenario, an execution S3′ of the virtual test of the test scenario, comprised by third scenario data set 22, is performed using the simulation model.

According to a further preferred embodiment, it is provided that after each generation of the third scenario data set, representing the logical test scenario, the comparison of first scenario data set 16, extracted from sensor data 12 of the motor vehicle journey detected by the at least one environment sensing sensor 26, with an output of the simulation model is carried out.

It is proven in this way that the model used is valid and that the logical scenario, which is used as the basis for the scenario-based testing, is within the validity range of the simulation model.

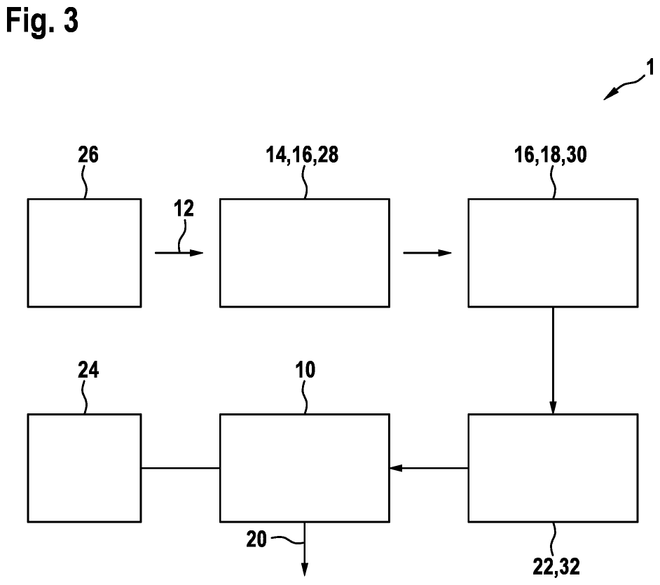

FIG. 3 shows a diagram of a system for the criteria-based creation of a scenarios library 10, having virtual vehicle environments, for testing highly automated driving functions of a motor vehicle according to the preferred embodiment of the invention.

The system comprises at least one environment sensing sensor 26 which is designed to provide, in particular pre-captured, sensor data 12 of a motor vehicle journey.

Further, the system comprises a determination unit 28 which is designed to determine, using predetermined criteria, an, in particular abstract, first scenario data set 16, representing a driving situation of interest 14 and comprised by sensor data 12, and a comparison unit 30 which is designed to compare first scenario data set 16, representing the driving situation of interest 14, with, in particular abstract, second scenario data sets 18 included in scenarios library 10.

The system furthermore comprises a generation unit 32 which is designed to create a third scenario data set (22), representing a logical test scenario, in scenarios library 10, or to generate a request to create the third scenario data set (22), representing the logical test scenario, in scenarios library 10, if the driving situation of interest 14 determined by first scenario data set 16 is not covered by any of the second scenario data sets 18 comprised by scenarios library 10.

Although specific embodiments have been illustrated and described herein, it is understandable by the skilled artisan that a plurality of alternative and/or equivalent implementations exist. It should be noted that the exemplary embodiment or exemplary embodiments are examples only and do not serve to limit the scope, applicability, or configuration in any way.

Rather, the above-mentioned summary and detailed description provide the skilled artisan with a convenient guide to implementing at least one exemplary embodiment, wherein it is understandable that various changes may be made in the functional scope and the arrangement of the elements, without departing from the scope of the appended claims and their legal equivalents.

In general, this application intends to cover changes or adaptations or variations of the embodiments presented herein. For example, an order of the method steps can be changed. The method can further be carried out sequentially or in parallel, at least in sections.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A computer-implemented method for the criteria-based creation of a scenarios library having virtual vehicle environments, the scenarios library being used for testing highly automated driving functions of a motor vehicle, the method comprising:
providing pre-captured sensor data of a motor vehicle journey detected by at least one environment sensing sensor;
determining, using predetermined criteria, an abstract, first scenario data set representing a driving situation of interest and comprised by the sensor data;
comparing the first scenario data set representing the driving situation of interest with abstract, second scenario data sets included in the scenarios library; and
creating a third scenario data set representing a logical test scenario in the scenarios library or generating a request to create the third scenario data set representing the logical test scenario in the scenarios library if the driving situation of interest determined by the first scenario data set is not covered by any of the second scenario data sets comprised by the scenario library.

2. The computer-implemented method according to claim 1, wherein the first scenario data set is formed by a time segment of a data stream comprised by the sensor data, and wherein the second scenario data sets comprised by the scenarios library, are formed by a machine-readable abstract description of a traffic situation of interest or formed by a test scenario.

3. The computer-implemented method according to claim 1, wherein if, after evaluation of a predetermined amount of sensor data, corresponding to a specific mileage of the motor vehicle, each determined first scenario data set is covered by the second scenario data sets included in the scenarios library, a message confirming a completeness of the scenarios library is generated.

4. The computer-implemented method according to claim 1, wherein if the determined first scenario data set, comprised by the sensor data and representing the driving situation of interest, is not covered by one of the second scenario data sets comprised by the scenarios library, a second scenario data set representing an abstract scenario is generated from the first scenario data set.

5. The computer-implemented method according to claim 1, wherein the third scenario data set, representing the logical test scenario, is stored in the scenarios library.

6. The computer-implemented method according to claim 1, wherein metadata are stored in the scenarios library for the second scenario data sets and/or the third scenario data sets.

7. The computer-implemented method according to claim 1, wherein, stored metadata in the scenarios library for the second scenario data sets and/or the third scenario data sets include one or more of:
information on a file of the sensor data;
boundary conditions of the traffic situations;
second scenario data set included in the scenarios library determined as belonging to the first scenario data set representing the driving situation of interest and comprised by the sensor data;
scenario parameters;
a speed of at least one motor vehicle; and/or
a distance between motor vehicles.

8. The computer-implemented method according to claim 1, wherein the third scenario data set, representing the logical test scenario, is generated using an algorithm which receives sensor data and an abstract test scenario comprised by the sensor data, as input data.

9. The computer-implemented method according to claim 1, wherein the determination of the first scenario data set, representing the driving situation of interest and comprised by the sensor data, is performed by classifying a driving situation of interest into classes representing abstract scenarios.

10. The computer-implemented method according to claim 1, wherein the determination, using predetermined criteria, of the first scenario data set representing the driving situation of interest and comprised by the sensor data and the comparison of the first scenario data set, representing the driving situation of interest, with second scenario data sets included in the scenarios library, are combined such that in the comparison step a filtering of the sensor data is carried out using the predetermined criteria.

11. The computer-implemented method according to claim 1, wherein a determination of the predetermined criteria for determining the first scenario data set, representing the driving situation of interest and comprised by the sensor data, is performed using a system weakness analysis.

12. The computer-implemented method according to claim 1, wherein the scenarios library comprises data of a test scenario taxonomy or a test scenario ODD taxonomy, and wherein the test scenario taxonomy is directed to a specific system to be tested.

13. A computer-implemented method for validating a model quality of a simulation model for performing a virtual test of a highly automated driving function of a motor vehicle, the method comprising:
providing a first scenario data set that is extracted from sensor data of a motor vehicle journey detected by at least one environment sensing sensor;
providing a third scenario data set, which is comprised by a scenarios library, for testing highly automated driving functions of a motor vehicle;
performing a virtual test of a test scenario comprised by the third scenario data set using a simulation model; and
comparing the first scenario data set, extracted from the sensor data of the motor vehicle journey detected by the at least one environment sensing sensor, with an output of the simulation model.

14. The computer-implemented method according to claim 13, wherein, if the first scenario data set, extracted from the sensor data of the motor vehicle journey detected by the at least one environment sensing sensor, and the output of the simulation model have a similarity exceeding a predetermined level, a validity of the algorithm for executing the highly automated driving functions of the motor vehicle is confirmed.

15. A system for a criteria-based creation of a scenarios library having virtual vehicle environments, for testing highly automated driving functions of a motor vehicle, the system comprising:
at least one environment sensing sensor that provides pre-captured sensor data of a motor vehicle journey;
a determination unit determines, using predetermined criteria, an abstract, first scenario data set representing a driving situation of interest and comprised by the sensor data;
a comparison unit, which compares the first scenario data set, representing the driving situation of interest, with abstract, second scenario data sets that are included in the scenarios library; and
a generation unit, which generates a third scenario data set, representing a logical test scenario, in the scenarios library or generates a request to create the third scenario data set, representing the logical test scenario, in the scenarios library if the driving situation of interest, determined by the first scenario data set, is not covered by any of the second scenario data sets comprised by the scenario library.

16. A computer program product with a computer program comprising software to carry out the method according to claim 1, wherein the computer program is executed on a computer.
